(19) United States
(12) Patent Application Publication
(10) Pub. No.: US 2014/0048322 A1
(43) Pub. Date: Feb. 20, 2014

(54) ELECTRONIC APPARATUS AND INSULATION STRUCTURE THEREOF

(71) Applicant: POWER MATE TECHNOLOGY CO., LTD., Taichung City (TW)

(72) Inventors: Lien-Hsing Chen, Taichung City (TW); Chia-Ti Lai, Taichung City (TW)

(73) Assignee: POWER MATE TECHNOLOGY CO., LTD., Taichung City (TW)

(21) Appl. No.: 13/648,960

(22) Filed: Oct. 10, 2012

(30) Foreign Application Priority Data
Aug. 20, 2012 (TW) 101130169

(51) Int. Cl. H05K 1/18

(52) U.S. Cl. 174/260

(57) ABSTRACT

An electronic apparatus and an insulation structure thereof are provided. The electronic apparatus comprises a circuit board, an insulation structure and a transformer. The circuit board has a top surface, a bottom surface and an opening extending across the top surface and the bottom surface. The insulation structure has a first standing plate and a top plate. The first standing plate is connected with the top plate, and the first standing plate is disposed on the circuit board and inserted into the opening of the circuit board. A bottom surface of the top plate faces towards the top surface of the circuit board. The transformer is disposed on the top plate of the insulation structure and on the top surface of the top plate.

### BACKGROUND OF THE INVENTION

1. Technical Field

The present invention relates to the insulation distance between electronic parts, and more particularly, to an insulation structure for use in an electronic apparatus.

2. Description of Related Art

As safety regulations on electronic circuits have been formulated by various countries and coalition governments, any electronic products sold to those countries must meet the norms of the corresponding safety regulations. In the insulation norms of transformers, the insulation distance between a primary side and a secondary side is specified by particular safety regulations.

As shown in FIG. 15, there is shown a schematic view depicting a conventional transformer soldered on a circuit board. The transformer 91 has a primary side pin 92 and a secondary side pin 94 which are soldered on the circuit board 99 respectively. Conventionally, a creepage distance is specified in order to meet the creepage distance specified by the insulation regulations, and the creepage distance refers to a shortest distance between two adjacent pins along a surface of an insulation object. Conventionally, the secondary side pin 94 of the transformer 91 is elongated so that the distance between the primary side pin 92 and the secondary side pin 94 of the transformer 91 can be increased. Likewise, it is also possible to elongate the primary side pin 92 to meet the norm of the insulation regulations.

However, the aforesaid method of increasing the insulation distance is usually unsuitable for use in electronic products having a limited space and, thus, cannot satisfy the requirements of modern lightweight and thin electronic products.

Furthermore, for example, U.S. Pat. No. 6,563,056 discloses an insulation barrier layer on a printed circuit board (PCB); and in order to increase the creepage distance between a primary side pin and a secondary side pin of the transformer, a housing of the transformer is provided with a lug extending from a side and a bottom thereof. However, because the lug extends from the side and the bottom of the housing of the transformer, it is also possible that creepage directly from the bottom of the lug to the top of the lug takes place to connect the primary side pin and the secondary side pin of the transformer, which makes it impossible for the lug to increase the creepage distance effectively.

### BRIEF SUMMARY OF THE INVENTION

An objective of the present invention is to provide an electronic apparatus and an insulation structure thereof. With disposition of the insulation structure, the insulation distance between a primary side and a secondary side of a transformer can meet the norm of the insulation regulations.

Accordingly, to achieve the aforesaid objective, the present invention provides an electronic apparatus and an insulation structure thereof. The electronic apparatus comprises a circuit board, an insulation structure and a transformer. The circuit board has a top surface, a bottom surface and an opening extending across the top surface and the bottom surface. The insulation structure has a first standing plate and a top plate. The first standing plate is connected with the top plate, and the first standing plate is disposed on the circuit board and inserted into the opening of the circuit board. A bottom surface of the top plate faces towards the top surface of the circuit board. The transformer is disposed on the top plate of the insulation structure and on the top surface of the top plate.

Preferably, the insulation structure further has a base and a bottom plate on which the base is disposed. The bottom plate faces directly towards the bottom surface of the circuit board. The first standing plate is inserted into the base.

### BRIEF DESCRIPTION OF THE SEVERAL VIEWS OF THE DRAWINGS

FIG. 1 to FIG. 3 are schematic views depicting an electronic apparatus according to a first preferred embodiment of the present invention respectively;

FIG. 4 and FIG. 5 are schematic views depicting an electronic apparatus according to a second preferred embodiment of the present invention respectively;

FIG. 6 to FIG. 8 are schematic views depicting an electronic apparatus according to a third preferred embodiment of the present invention respectively;

FIG. 9 to FIG. 11 are schematic views depicting an electronic apparatus according to a fourth preferred embodiment of the present invention respectively;

FIG. 12 to FIG. 14 are schematic views depicting an electronic apparatus according to a fifth preferred embodiment of the present invention respectively; and

FIG. 15 is a schematic view depicting a conventional transformer soldered on a circuit board.

### DETAILED DESCRIPTION OF THE INVENTION

To describe the technical features of the present invention in detail, the present invention will be described hereinbelow with reference to the following preferred embodiments and the attached drawings.

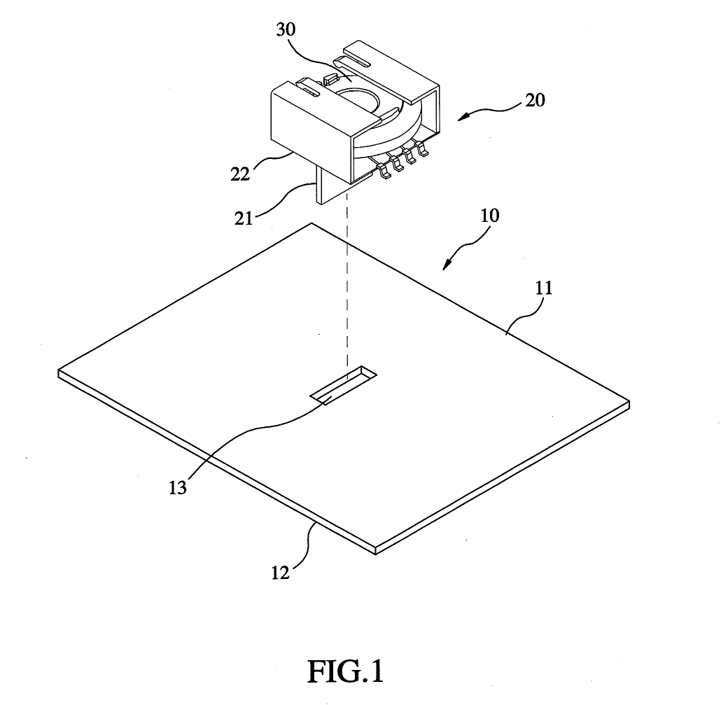

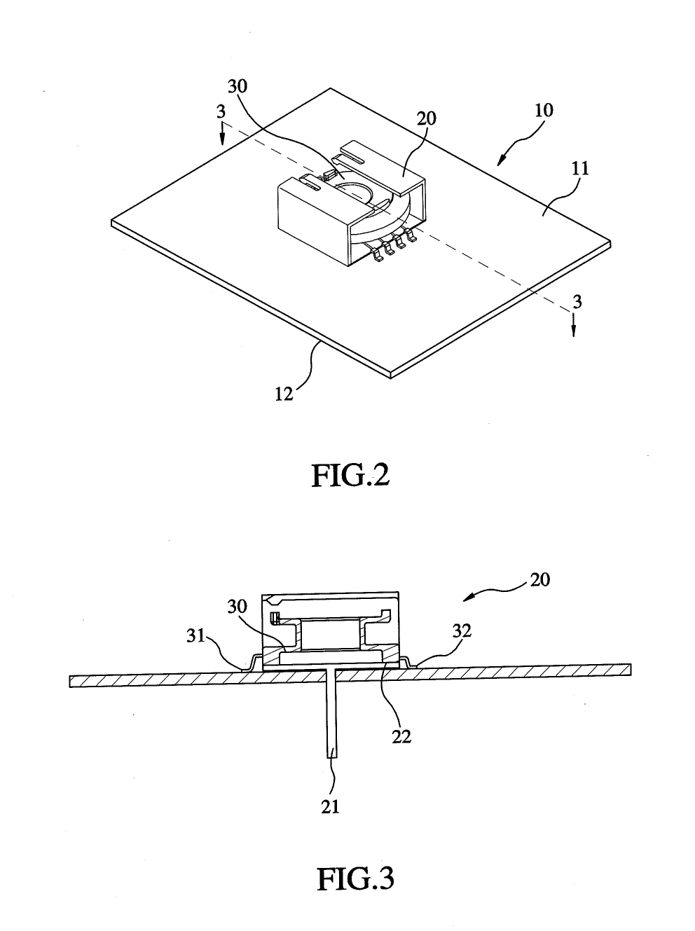

As shown in FIG. 1 and FIG. 2, FIG. 1 is an exploded view depicting an electronic apparatus according to a first preferred embodiment of the present invention, and FIG. 2 is a perspective assembly view depicting the electronic apparatus of the first preferred embodiment. The electronic apparatus comprises a circuit board 10, an insulation structure 20 and a transformer 30. The circuit board 10 has a top surface 11, a bottom surface 12 and an opening 13 extending across the top surface 11 and the bottom surface 12.

The insulation structure 20 has a first standing plate 21 and a top plate 22. The first standing plate 21 is connected with the top plate 22, and the first standing plate 21 is disposed on the circuit board 10 and inserted into the opening 13 of the circuit board 10. A bottom surface of the top plate 22 faces towards the top surface 11 of the circuit board 10. It shall be noted that, a top surface of the top plate 22 shown also has other structures; however, those structures have no influence on the objective to be achieved by the present invention and, thus, will not be further described herein. Preferably, the first standing plate 21 and the top plate 22 are integrally formed and are perpendicular to each other.

The transformer 30 is disposed on the top plate 22 of the insulation structure and on the top surface of the top plate 22.

As shown in FIG. 3, there is shown a cross-sectional view depicting the electronic apparatus of FIG. 2. The transformer 30 has a primary side pin 31 and a secondary side pin 32 which are soldered on the top surface of the circuit board 10 respectively. However, in practice, the primary side pin 31 and the secondary side pin 32 of the transformer 30 may also extend through the top surface and the bottom surface of the circuit board 10 so as to be soldered on the bottom surface of the circuit board 10. Because of the aforesaid configuration of the insulation structure 20 of the present invention, the insulation distance (i.e., the creepage distance) formed between the primary side pin 31 and the secondary side pin 32 of the transformer 30 can be increased to better meet the norms of the safety regulations owing to the structure of the first standing plate 21 and the top plate 22. Further, it is also possible to meet different insulation regulations by adjusting dimensions of the first standing plate 21 and the top plate 22. However, the first standing plate 21 may also be located at other positions (e.g., two sides) of the top plate 22 in practice, so the present invention is not limited to what depicted in FIG. 3. Furthermore, the first standing plate 21 and the top plate 22 may also be of a non-perpendicular structure in practice, so the present invention is not limited to the aforesaid perpendicular structure.

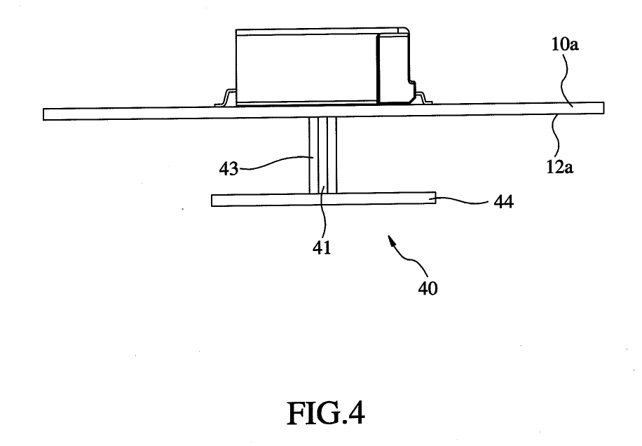

As shown in FIG. 4, there is shown a side view depicting an electronic apparatus according to a second preferred embodiment of the present invention. The second preferred embodiment is generally the same as the first preferred embodiment, but differs from the first preferred embodiment mainly in that: the insulation structure 40 further has a base 43 and a bottom plate 44. The base 43 is disposed on the bottom plate 44, and the bottom plate 44 faces directly towards the bottom surface of the circuit board 10a. The first standing plate 41 is inserted into the base 43. Preferably, the bottom plate 44 and the circuit board 10a have a space therebetween. Thus, in the second preferred embodiment, the insulation creepage distance between the primary side and the secondary side of the transformer can be increased by means of the structure of the bottom plate 44. If the insulation norm can already be met by additionally providing the structure of the bottom plate 44, then it is unnecessary for the bottom plate 44 and the circuit board 10a to keep the space therebetween; i.e., the first standing plate 41 and the base 43 can be reduced in height.

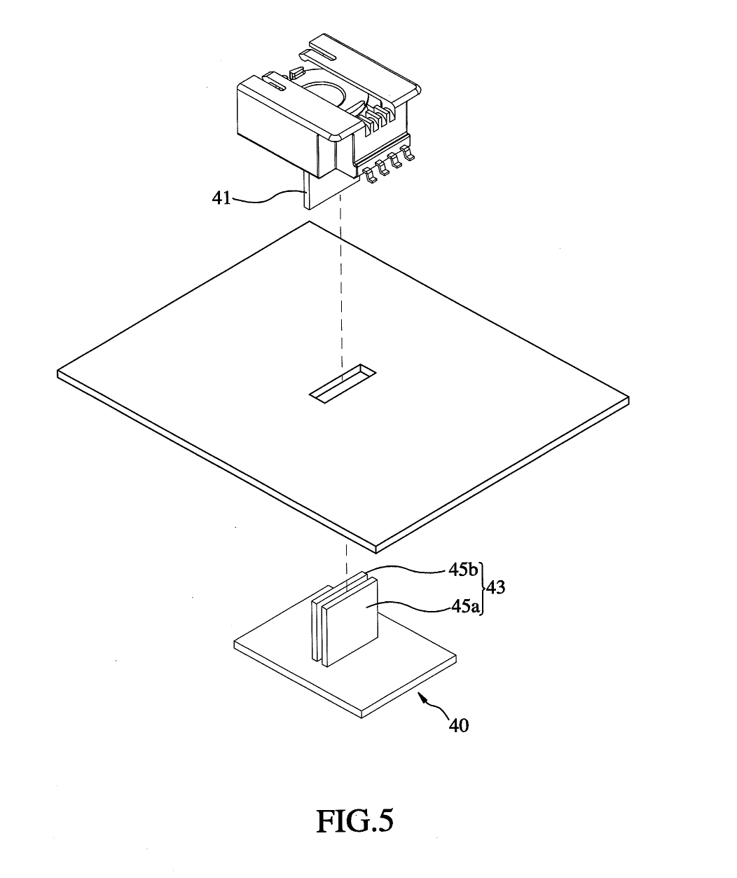

As shown in FIG. 5, there is shown an exploded view depicting the electronic apparatus of FIG. 4. The base 43 has two sandwiching plates 45a, 45b that sandwich two opposite surfaces of the first standing plate 41 therebetween. Thus, the assembly of the insulation structure 40 can be completed.

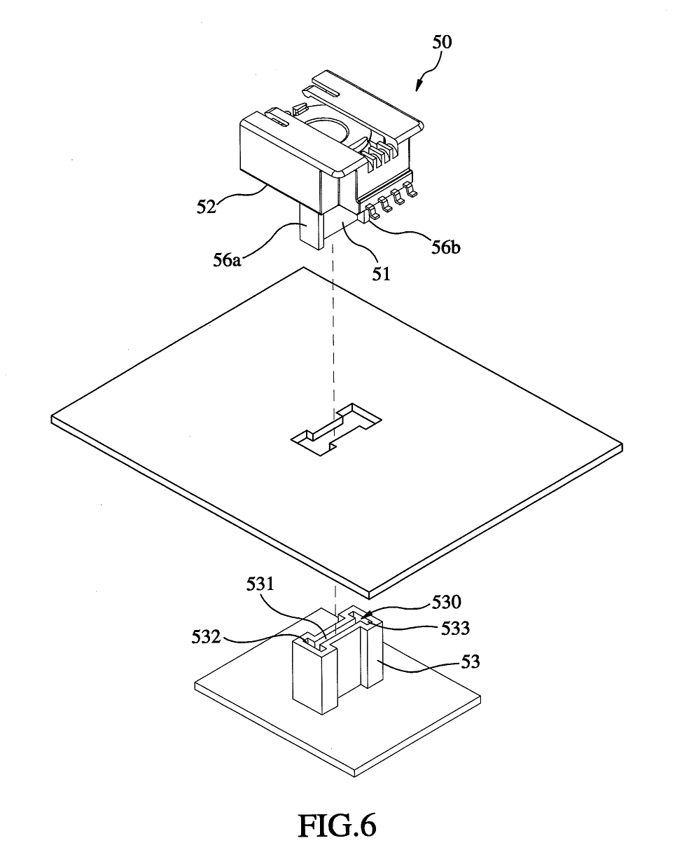

As shown in FIG. 6, there is shown an exploded view depicting an electronic apparatus according to a third preferred embodiment of the present invention. The insulation structure 50 further has two sidewalls 56a, 56b, which are connected with the first standing plate 51 and the top plate 52 respectively and are located at two opposite sides of the first standing plate 51. The two sidewalls 56a, 56b face towards each other. The base 53 has a groove 530 comprising an elongate section 531 and two side sections 532, 533 perpendicular to the elongate section 531 respectively. The elongate section 531 is adapted to receive the first standing plate 51, and the two side sections 532, 533 are adapted to receive the two sidewalls 56a, 56b respectively.

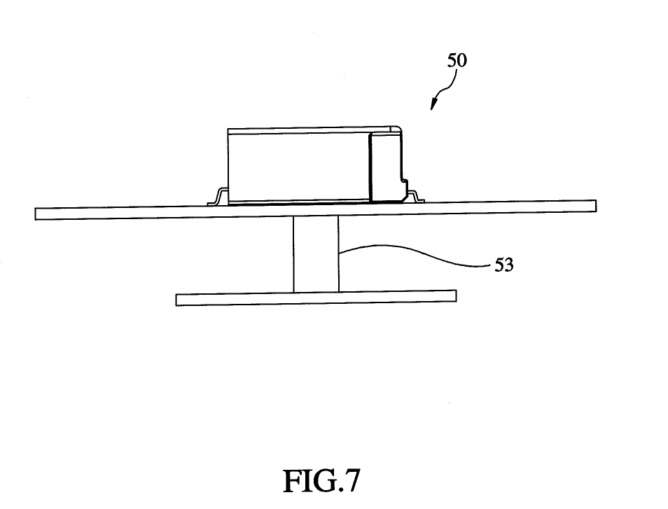

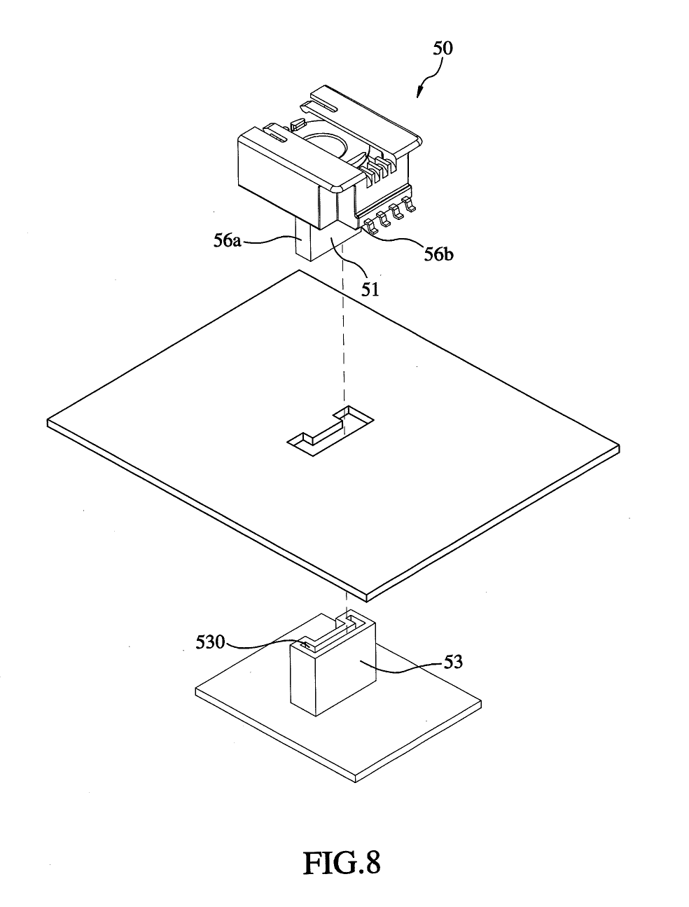

As shown in FIG. 7, there is shown a side view depicting the electronic apparatus of FIG. 6 after being assembled. Because of the aforesaid configuration of the insulation structure 50, the first standing plate 51 and the two sidewalls 56a, 56b in FIG. 6 can be enclosed in the base 53 after the assembly is completed. Furthermore, the two sidewalls 56a, 56b may also be connected with the first standing plate 51 as shown in FIG. 8, but the groove 530 of the base 53 must match with the structure adjustment of the first standing plate 51 and the two sidewalls 56a, 56b for purpose of assembling the insulation structure 50.

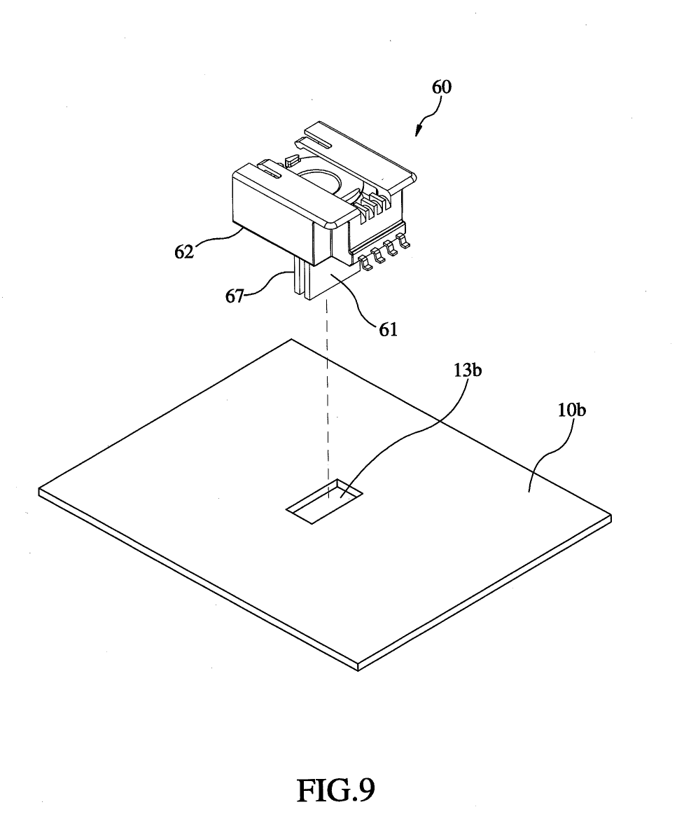

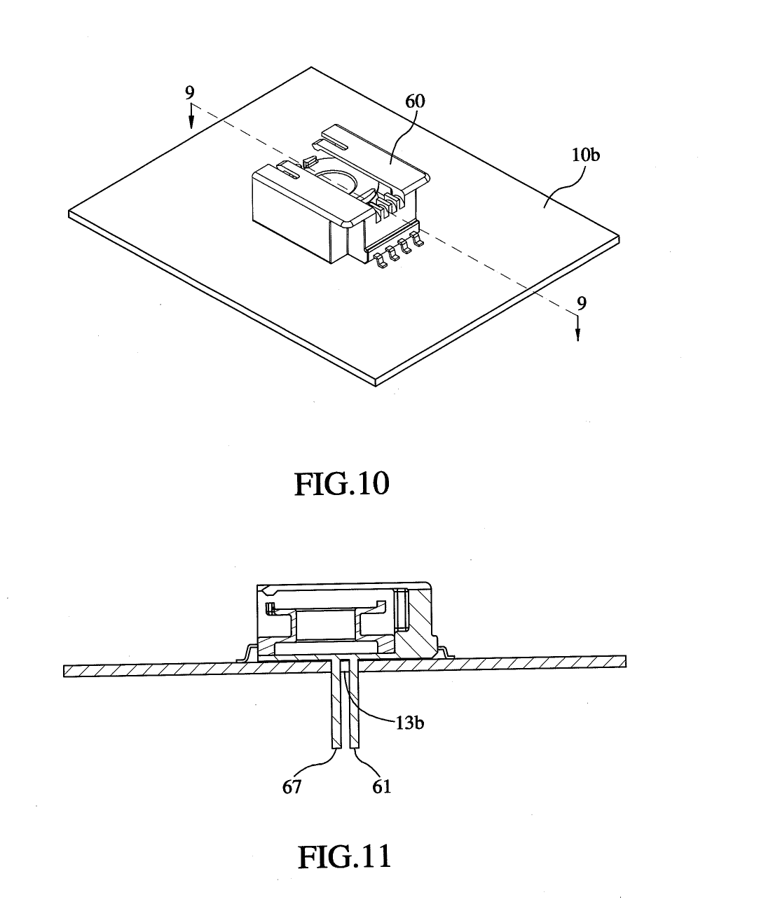

As shown in FIG. 9 and FIG. 10, FIG. 9 is an exploded view depicting an electronic apparatus according to a fourth preferred embodiment of the present invention, and FIG. 10 is a perspective assembly view depicting the electronic apparatus of FIG. 9. The fourth preferred embodiment differs from the first preferred embodiment mainly in that: the insulation structure 60 further has a second standing plate 67. The second standing plate 67 is connected with the top plate 62, and is spaced apart from and arranged abreast with the first standing plate 61. The second standing plate 67 is disposed on the circuit board 10b and inserted into the opening 13b of the circuit board 10b.

As shown in FIG. 11, there is shown a cross-sectional view depicting the electronic apparatus of FIG. 10. In this embodiment, the opening 13b is larger than the opening 13 described in the first preferred embodiment, and both the first standing plate 61 and the second standing plate 67 extend through the opening 13b. Thus, the insulation creepage distance can be increased through disposition of the second standing plate 67. Therefore, if a creepage distance identical to that of the first preferred embodiment is desired, then when the second standing plate 67 is additionally provided, the height of the first standing plate 61 and the second standing plate 67 can be smaller than that of the first standing plate of the first preferred embodiment so that the overall height of the insulation structure is reduced. In practice, more such structures and configurations as the second standing plate may also be additionally provided to reduce the height of those standing plates.

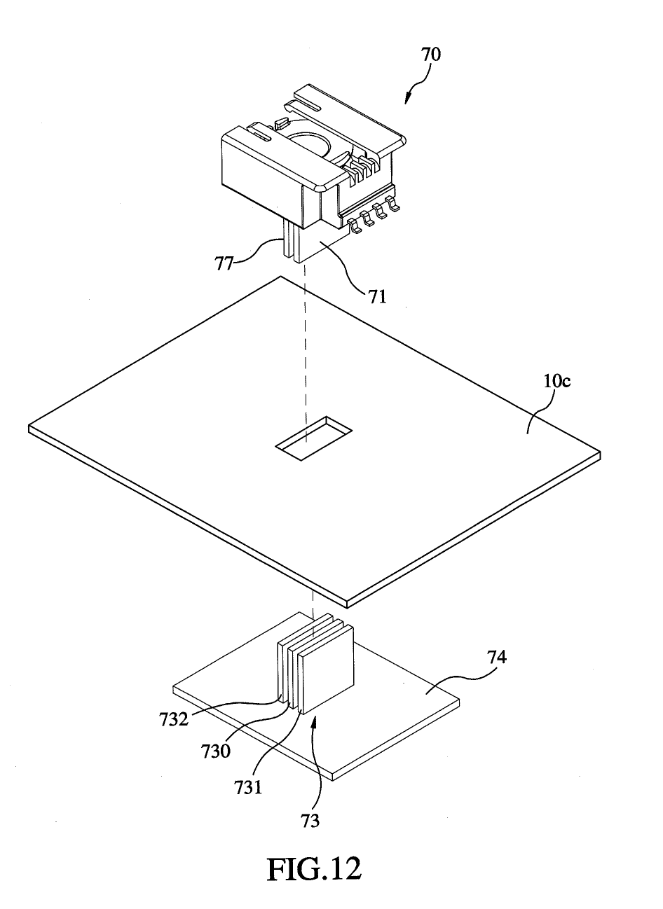

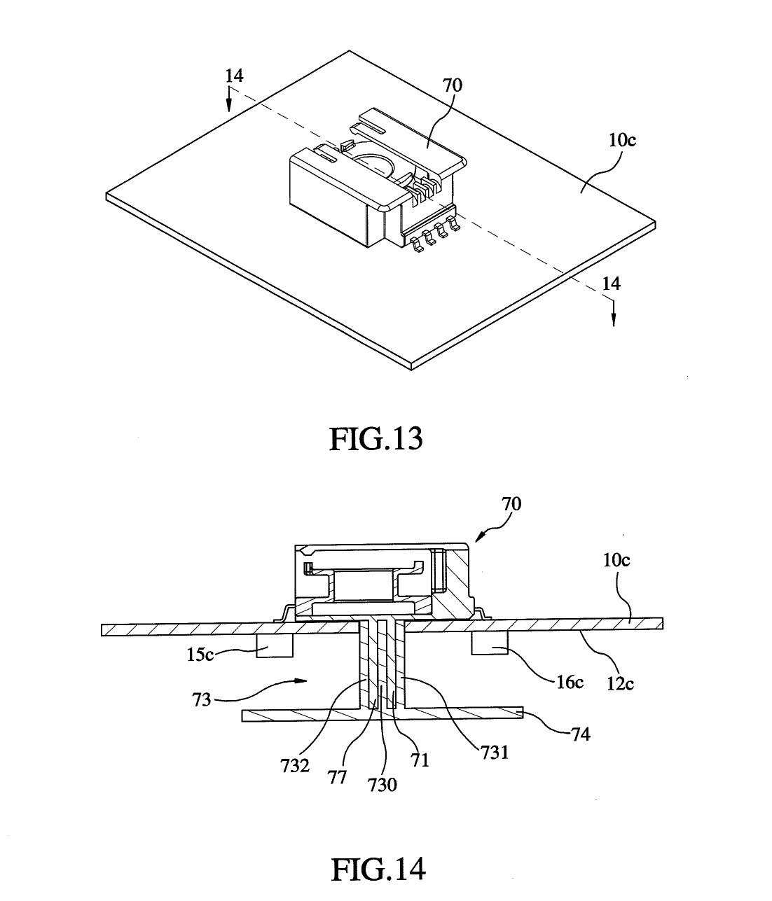

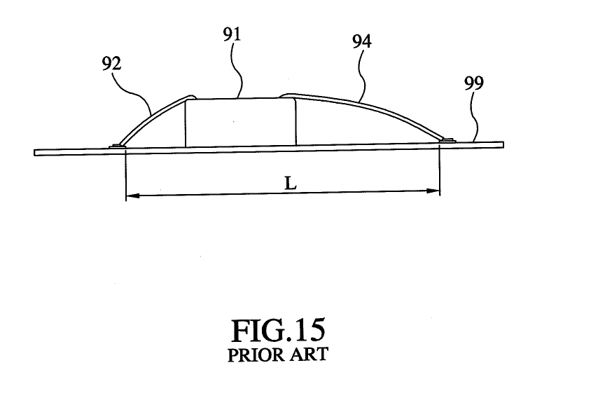

As shown in FIG. 12 to FIG. 14, FIG. 12 is an exploded view depicting an electronic apparatus according to a fifth preferred embodiment of the present invention, FIG. 13 is a perspective assembly view depicting the electronic apparatus of FIG. 12, and FIG. 14 is a cross-sectional view depicting the electronic apparatus of FIG. 13. The insulation structure 70 further has a base 73 and a bottom plate 74 on which the base 73 is disposed. The base 73 has a tongue plate 730 and two sandwiching plates 731, 732 located at two opposite sides of the tongue plate 730. The tongue plate 730 abuts against inner surfaces of the first standing plate 71 and the second standing plate 77, the two sandwiching plates 731, 732 abut against outer surfaces of the first standing plate 71 and the second standing plate 77 respectively, and the bottom plate 74 faces directly towards the bottom surface 12c of the circuit board 10c. Thus, the fifth preferred embodiment has a more stable assembly structure as compared to the first preferred embodiment, and has an insulation structure which is easier to produce as compared to the third preferred embodiment.

Furthermore, as shown in FIG. 14, the bottom surface 12c of the circuit board 10c is further provided with two electronic components 15c, 16c which are located at two sides of the base 73. Thus, the creepage distance between the two electronic components 15c, 16c can also be increased by means of the insulation structure 70 to meet the insulation norm. Likewise, the bottom surface of the circuit board described in the first to the fourth preferred embodiments may also be provided with the aforesaid two electronic components 15c, 16c, but the two electronic components 15c, 16c need be separated by the insulation structure.

Particularly, the structure on the top surface of the top plate in the second to the fifth preferred embodiments also has no influence on the objective to be achieved by the present invention as described in the first embodiment and, thus, will not be further described herein. The insulation structure described in the first to the fifth preferred embodiments may also be used to connect a circuit board assembly as described in Description of Related Art (i.e., the circuit board assembly has two circuit boards spaced apart from and arranged abreast with each other). Thus, the two circuit boards spaced apart from and arranged abreast with each other can have an opening of the present invention defined therebetween for the standing plates (i.e., the first standing plate and the second standing plate) of the insulation structure to be inserted therein. However, because of the structure of the top plate of the present invention, the problems with the prior art can be overcome and the production becomes easier.

What is claimed is:

1. An electronic apparatus, comprising:
a circuit board, having a top surface, a bottom surface and an opening extending across the top surface and the bottom surface;
an insulation structure, having a first standing plate and a top plate, wherein the first standing plate is connected with the top plate, the first standing plate is disposed on the circuit board and inserted into the opening of the circuit board, and a bottom surface of the top plate faces towards the top surface of the circuit board; and
a transformer, being disposed on the top plate of the insulation structure and on the top surface of the top plate.

2. The electronic apparatus of claim 1, wherein the insulation structure further has a base and a bottom plate on which the base is disposed, the bottom plate faces directly towards the bottom surface of the circuit board, and the first standing plate is inserted into the base.

3. The electronic apparatus of claim 2, wherein the base has two sandwiching plates that sandwich two opposite surfaces of the first standing plate therebetween.

4. The electronic apparatus of claim 2, wherein the insulation structure further has two sidewalls connected with the first standing plate and the top plate respectively, located at two opposite sides of the first standing plate and facing towards each other, and wherein the base has a groove comprising an elongate section and two side sections perpendicular to the elongate section respectively, the elongate section is adapted to receive the first standing plate and the two side sections are adapted to receive the two sidewalls.

5. The electronic apparatus of claim 1, wherein the insulation structure further has a second standing plate connected with the top plate and spaced apart from and arranged abreast with the first standing plate, and the second standing plate is disposed on the circuit board and inserted into the opening of the circuit board.

6. The electronic apparatus of claim 5, wherein the insulation structure further has a base and a bottom plate, the base is disposed on the bottom plate and has a tongue plate and two sandwiching plates located at two opposite sides of the tongue plate, the tongue plate abuts against inner surfaces of the first standing plate and the second standing plate, the two sandwiching plates abut against outer surfaces of the first standing plate and the second standing plate respectively, and the bottom plate faces directly towards the bottom surface of the circuit board.

7. An insulation structure disposed on a circuit board assembly and adapted to support a transformer, the insulation structure comprising:
a first standing plate, inserted through the circuit board assembly; and
a top plate connected with the first standing plate and facing towards a top surface of the circuit board assembly, wherein the transformer is disposed on a top surface of the top plate.

8. The insulation structure of claim 7, further having a base and a bottom plate on which the base is disposed, wherein the bottom plate faces directly towards a bottom surface of the circuit board assembly, and the first standing plate is inserted into the base.

9. The insulation structure of claim 8, further having two sidewalls connected with the first standing plate and the top plate respectively, located at two opposite sides of the first standing plate and facing towards each other, wherein the base has a groove comprising an elongate section and two side sections perpendicular to the elongate section respectively, the elongate section is adapted to receive the first standing plate and the two side sections are adapted to receive the two sidewalls.

10. The insulation structure of claim 8, further having a second standing plate connected with the top plate and spaced apart from and arranged abreast with the first standing plate, wherein the second standing plate is inserted through the circuit board assembly, the base has a tongue plate and two sandwiching plates located at two opposite sides of the tongue plate, the tongue plate abuts against inner surfaces of the first standing plate and the second standing plate, the two sandwiching plates abut against outer surfaces of the first standing plate and the second standing plate respectively, and the bottom plate faces directly towards the bottom surface of the circuit board assembly.
